(19) United States
(12) Patent Application Publication
(10) Pub. No.: US 2024/0109029 A1
(43) Pub. Date: Apr. 4, 2024

(54) EXHAUST GAS ABATEMENT SYSTEM

(71) Applicant: Edwards Vacuum LLC, Sanborn, NY (US)

(72) Inventor: Imad Mahawili, Roseville, CA (US)

(21) Appl. No.: 18/474,594

(22) Filed: Sep. 26, 2023

Related U.S. Application Data
(60) Provisional application No. 63/378,259, filed on Oct. 4, 2022.

(51) Int. Cl. B01D 53/75; B01D 53/78

(52) U.S. Cl. CPC B01D 53/75; B01D 53/78; B01D 2252/103; B01D 2258/0216

(57) ABSTRACT

The present invention provides an exhaust gas abatement system for use in semiconductor processing. The system comprising a vacuum pump having an exhaust outlet, a water eductor coupled to the exhaust outlet of the vacuum pump, and a separator coupled to the water eductor. The system further comprises an exhaust gas abatement apparatus coupled to a gaseous exhaust outlet of the separator. Wherein the system is configured such that, in use, an exhaust flow from the exhaust outlet of the vacuum pump is conveyed to the separator via the water eductor, and wherein the separator is configured, in use, to separate a gaseous component of the exhaust flow from the non-gaseous component of the exhaust flow.

### CROSS-REFERENCE OF RELATED APPLICATION

The present application is based on and claims the benefit of U.S. provisional patent application Ser. No. 63/378,259, filed Oct. 4, 2022, the content of which is hereby incorporated by reference in its entirety.

### FIELD

The present invention relates to an exhaust gas abatement system for use in semiconductor processing. The present invention also relates a method of abating exhaust gas from a semiconductor processing chamber, and to the use of a water eductor and a separator in an exhaust gas abatement system for semiconductor production.

### BACKGROUND

Semiconductor products are created by the processing of single crystal silicon wafers through numerous lithography, deposition and etch steps. Various precursor chemical vapours are used when performing these steps, which are usually performed under high vacuum. Typically, the efficiency of use of said chemical vapours in the fabrication of semiconductor devices is fairly low. It is estimated that in some cases over fifty percent of the precursor chemical vapours exit the semiconductor processing chamber through the outlet connected to the vacuum pump (i.e. vacuum fore-line). Subsequently, the precursor chemical vapours may be conveyed through the vacuum pump in the form of an exhaust flow.

As the exhaust flow exits the exhaust of the vacuum pump it is typically diluted with nitrogen gas to reduce the likelihood of condensation of chemical vapours. The nitrogen gas also aids in reducing the flammability of the resulting mixture, thereby improving safety. Additionally, the pump exhaust line is typically heated to reduce the likelihood of condensation of the volatile chemical vapours. The nitrogen-diluted chemical vapour mixture is conveyed to an abatement system to be destroyed using high temperatures generated by either combustion (e.g. of methane gas) or by electric arc discharge.

The vacuum pump exhaust line is typically from about 15 feet (4.572 m) to about 40 feet (12.192 m) in length. The vacuum pump exhaust line connects the vacuum pump to the abatement system.

The presence of precursor chemical vapours in the vacuum pump exhaust line may cause a number of different issues depending on the chemical vapours and the conditions.

By way of example, titanium tetrachloride is used in the chemical vapor deposition of titanium nitride thin films when reacted with ammonia gas. Titanium tetrachloride is a liquid at room temperature and is highly reactive with water. When titanium tetrachloride is used in semiconductor processing, the vacuum pump exhaust composition may comprise unreacted titanium tetrachloride and ammonia gas in nitrogen. Any “cold spot” along the exhaust line may cause condensation of titanium tetrachloride. This may result in hazardous conditions due the accumulation of liquid chemicals that can undergo subsequent reactions and cause localized corrosion in the pump exhaust line. This may be particularly hazardous in the presence of water condensation, either during semiconductor processing or routine maintenance.

Tungsten hexafluoride, with a boiling point of 17° C., is reactive with water and is widely used in semiconductor processing. Dilution of the vacuum pump exhaust flow containing tungsten hexafluoride with nitrogen and heating of the vacuum pump exhaust line is critical for safe and continuous operation.

Ammonium nitrate is a product of various chemical vapor phase reactions that can take place in the semiconductor processing chamber or along the vacuum fore-line. Ammonium nitrate has a melting point of 169.6° C. and a boiling point of 210° C. If the pump exhaust line is not heated to at least 250° C., ammonium nitrate may condense and deposit. The accumulation of ammonium nitrate in the vacuum pump exhaust line may create localized deposits that can detonate under reactions with pump exhaust gases or due to friction/vibration of the exhaust line, e.g. during maintenance schedules.

Advanced semiconductor processing by atomic layer deposition (ALD) typically employs vapours of chemical precursors such as trimethyl aluminium (TMA). Trimethyl aluminium has a boiling point of about 125° C. to 130° C., and reacts aggressively with water. In atomic layer deposition processes, the vacuum pump exhaust line must be heated uniformly along its length to a temperature of at least 200° C. Any cold spot in the vacuum exhaust line could result in the condensation of trimethyl aluminium, requiring removal via an extremely hazardous and costly maintenance procedure. Condensation of trimethyl aluminium at the entrance of the exhaust gas abatement system is well reported. Accordingly, this may require increased frequency of maintenance under potentially dangerous conditions.

In other thin film processes, tetrakis (dimethylamido) titanium precursor may be used. The exhaust gas stream from the use of this precursor may lead to significant particulate deposition in the vacuum pump exhaust line. This may plug the input nozzles of the abatement systems, resulting in frequent down time and high production costs.

Accordingly, there is a desire to provide an improved exhaust gas abatement system to reduce the deposition of chemical precursors, thereby reducing the required frequency of, and risk associated with, maintenance.

The present invention aims to solve, at least in part, these and other problems associated with the prior art. Embodiments described in further detail below seek to provide an improved exhaust gas abatement system for use in semiconductor processing.

The discussion above is merely provided for general background information and is not intended to be used as an aid in determining the scope of the claimed subject matter. The claimed subject matter is not limited to implementations that solve any or all disadvantages noted in the background.

### SUMMARY

The invention is defined in the appended set of claims. In a first aspect, the present invention provides an exhaust gas abatement system for use in semiconductor processing. The system comprises a vacuum pump comprising an exhaust outlet, and a water eductor coupled to the exhaust outlet of the vacuum pump. The system further comprises a separator coupled to the water eductor. The system further comprises an exhaust gas abatement apparatus, preferably an abatement furnace, coupled to a gaseous exhaust outlet of the separator. The system is configured such that, in use, the exhaust flow from the exhaust outlet of the vacuum pump is conveyed to the separator via the water eductor. The separator is configured, in use, to separate a gaseous component of the exhaust flow and a non-gaseous component of the exhaust flow.

For the purposes of the present invention, semiconductor processing may comprise the processing of silicon wafers through one or more lithography, deposition and etch steps. The semiconductor processing may include, for example, one or more physical vapour deposition, chemical vapour deposition, electrochemical deposition, molecular beam epitaxy, and/or atomic layer deposition steps.

The exhaust flow from said semiconductor processing step(s) may include precursor chemical vapour(s). Typically, the exhaust flow may be diluted with nitrogen gas. Preferably, the exhaust gas may be diluted with nitrogen gas at the exhaust of the vacuum pump. Advantageously, this may reduce the risk of condensation of precursor chemical vapours, and may lower the flammability of the exhaust flow. Nitrogen gas may be introduced into the exhaust flow at a flow rate of from about 20 slm to about 150 slm.

In use, the vacuum pump may be configured to evacuate a chamber in which semiconductor processing occurs. The vacuum pump may be connected to an exhaust outlet of the semiconductor processing chamber during use. The exhaust flow from the semiconductor processing chamber may be conveyed through the vacuum pump and exit via the vacuum pump exhaust outlet. The exhaust flow may be primarily gaseous, but may also include non-gaseous material (e.g. solid and/or liquid components). During operation, the pressure at the pump outlet is typically about 1 atmosphere.

The skilled person will appreciate that the present invention may be applicable with a variety of types of vacuum pump, and will be able to select an appropriate vacuum pump according to the requirements of the specific application. The vacuum pump may be, for example, a turbomolecular pump and/or a multistage roots pump. By way of example, the vacuum pump may be an iGX dry pump, as produced by Edwards Limited.

The water eductor may preferably be arranged at or adjacent to the exhaust outlet of the vacuum pump. In the water eductor, the exhaust flow, including any chemical precursors, may be mixed with water. This mixing may be encouraged by the relatively high flow rate of the water injected into the water eductor. Water-reactive chemicals in the exhaust flow may react with and/or dissolve in the water in the water eductor and thereby be removed from the gaseous component of the exhaust flow.

Additionally or alternatively, the water eductor may remove solid components from the exhaust flow. For example, solid deposits and/or aerosol particles formed at the exhaust outlet of the vacuum pump may be dissolved when mixed with water in the water eductor. Advantageously, positioning the water eductor adjacent to the exhaust outlet of the vacuum pump may reduce the likelihood of condensation of chemical vapours in the vacuum pump exhaust line prior to the water eductor.

The separator may preferably be arranged at or adjacent to an outlet of the water eductor. Preferably, the inlet of the separator is directly connected to the outlet of the water eductor. The exhaust flow from the water eductor may flow directly into the inlet of the separator. Advantageously, conveying the exhaust flow through the separator may enable the separation of the gaseous component of the exhaust flow from the non-gaseous component of the exhaust flow.

The exhaust gas abatement apparatus may be configured to treat the gaseous component of the exhaust flow from the separator. Said treatment may include, for example, abatement in a gas (e.g. natural gas or methane) burner or electric arc burner. Preferably, the exhaust gas abatement apparatus is an abatement furnace. For example, the exhaust gas abatement apparatus may comprise an inward-fired combustor, a plasma chamber, and/or electric arc discharge chamber. By way of example, the exhaust gas abatement apparatus may be an Atlas™ as produced by Edwards Limited.

The exhaust gas abatement apparatus may be coupled to a gaseous exhaust outlet of the separator. Typically, the exhaust gas abatement apparatus may be coupled to the gaseous exhaust outlet of the separator via an exhaust line. The exhaust line may be heated to a temperature of at least 100° C., preferably at least 200° C.

In typical systems of the prior art, the vacuum pump exhaust outlet is fluidly connected to the exhaust gas abatement apparatus via a vacuum pump exhaust line. The vacuum pump exhaust line may be up to about 40 feet (i.e. 12.192 m) in length. It has been found that in prior art systems, condensation of precursor chemical vapours in the vacuum pump exhaust line is particularly prevalent. However, in the present invention, the conveyance of the exhaust flow through the water eductor and the separator between the vacuum pump exhaust outlet and the abatement apparatus may remove water reactive precursor chemical vapours from the exhaust flow. Thus, the likelihood of condensation of precursor chemical vapours in the exhaust line may be reduced.

Advantageously, the present invention may remove water-reactive precursor chemical vapours from the exhaust flow, along with solid deposits in the vacuum pump or vacuum pump exhaust line. Furthermore, inorganic acids present in the exhaust flow may also dissolve in the water jet. This may reduce deposit formation in the vacuum pump exhaust line and/or the exhaust gas abatement apparatus. Particularly, this may reduce the likelihood of condensation of precursor chemical vapours at the vacuum pump exhaust outlet and/or the inlet of the exhaust gas abatement apparatus. Therefore, the frequency of maintenance may be reduced, and the safety of the system may be improved.

Typically, the water eductor may comprise an inlet coupled to the exhaust outlet of the vacuum pump. The water eductor may comprise a nozzle configured for the injection of water. The water eductor may further comprise a mixing throat. In use, the exhaust flow from the vacuum pump may mix with the injected water in the mixing throat. The water eductor may further comprise an expander diffuser coupled to the mixing throat. The expander diffuser may be defined by a chamber having an increasing cross-sectional area in the direction of an outlet of the water eductor.

The inlet of the water eductor may be directly connected to the exhaust outlet of the vacuum pump. Alternatively, the inlet of the water eductor may be coupled to the exhaust outlet of the vacuum pump by an exhaust line (e.g. a pipe). In use, the water eductor may produce a vacuum at the exhaust inlet. Advantageously, this may draw gas through the exhaust outlet of the vacuum pump, and/or may reduce backflow of gas through said exhaust outlet.

For the purpose of the present invention, water may be defined as water, distilled water or an aqueous solution. In some embodiments, the water injected through the nozzle of the water eductor may comprise recycled wastewater from an acid tank of the exhaust gas abatement apparatus, and/or recycled waste water from elsewhere in the semiconductor processing plant. The composition of the water or aqueous solution may depend on the composition of the exhaust gas flow, and the specific semiconductor process that is occurring.

The water may be supplied to the nozzle by a pump. The pump may be part of the exhaust gas abatement apparatus or may be a separate component. The water may provide what may be referred to as the motive fluid for the water eductor. The water eductor is typically a venturi eductor. Typically, during use, the velocity of the water injected through the nozzle may be greater than the velocity of the exhaust flow through the inlet of the water eductor. Advantageously, this may improve mixing of the exhaust flow and the water.

The cross-sectional area of the water eductor may reduce at the mixing throat. Advantageously, this may promote mixing of the water and the exhaust flow in the mixing throat.

The expander diffuser may be directly connected to an outlet of the mixing throat. The cross-sectional area of the chamber defining the expander diffuser may increase substantially continuously in the direction of the outlet of the water eductor. The chamber defining the expander diffuser may have a first (e.g. proximal) cross-sectional area adjacent to the mixing throat. The chamber defining the expander diffuser may have a second (e.g. distal) cross-sectional area adjacent to the outlet of the water eductor. The first cross-sectional area may be less than the second cross-sectional area. The cross-sectional area of the chamber defining the expander diffuser may increase substantially continuously between the first cross-sectional area and the second cross-sectional area. The chamber defining the expander diffuser may be substantially frustoconical.

The water may be injected through the nozzle under pressure. As the water passes through the nozzle, the velocity of the water may increase. This may result in a decrease of the pressure of the water, in accordance with Bernoulli's principle. The water may then mix with the exhaust flow from the vacuum pump exhaust outlet in the mixing throat, and transfer kinetic energy thereto. As the exhaust and water mixture exits the mixing throat and travels through the expander diffuser, the cross-sectional area of the chamber defining the expander diffuser increases. Accordingly, the velocity of the exhaust and water mixture may decrease, and the pressure may increase. This may generate a pressure differential between the outlet of the water eductor and the exhaust inlet, resulting in the generation of a vacuum at the inlet of the water eductor via the Venturi effect.

The water eductor may comprise a valve configured to enable the flow rate of water injection through the nozzle to be controlled. Preferably, the valve be a fluid shut off valve.

Advantageously, the water eductor may enable a vacuum to be generated at the inlet of the water eductor. For the purposes of the present invention, the vacuum produced by the water eductor may be defined as a relatively low pressure in comparison to the pressure at the exhaust outlet of the vacuum pump. The pressure at the exhaust outlet of the vacuum pump is typically about 1 atmosphere. The vacuum may be generated despite the water eductor having no mechanical moving parts. The vacuum generated may be variable according to the dimensions of the water eductor, the components selected (e.g. nozzle), the water flow rate, and the water pressure. The water eductor may also beneficially allow for mixing of three-phase exhaust flow (i.e. exhaust flow comprising gaseous, liquid, and/or solid components). Furthermore, the water eductor provides a low-maintenance solution to the problems associated with systems of the prior art.

Typically, the separator may comprise an inlet coupled to the outlet of the water eductor. The separator may further comprise a first chamber comprising a first liquid outlet and the gaseous exhaust outlet. The first chamber may be configured, in use, to be partially filled with liquid (e.g. water) such that an uppermost surface of the liquid defines a fill-line. The first liquid outlet will usually be arranged below the fill-line and the gaseous exhaust outlet is normally arranged above the fill-line. The gaseous exhaust outlet may be connected to the exhaust gas abatement apparatus.

Preferably, the separator may further comprise a second chamber comprising a liquid inlet in fluid communication with the first liquid outlet of the first chamber. The second chamber may further comprise a further (i.e. second) liquid outlet. The second chamber may be arranged such that, in use, liquid flows through the second chamber in a direction substantially opposite to the direction of liquid flow through the first chamber. When in use, the second chamber may be located below the first chamber, such that any gas in the liquid is biased upwards towards the gas outlet.

The separator may be configured, in use, to separate the gaseous component of the exhaust flow from the non-gaseous component of the exhaust flow. The gaseous component of the exhaust flow may comprise gases that are not dissolved in the water and/or any gaseous by-products of reactions between the precursor chemical vapours and water. For example, the gaseous component may comprise nitrogen, oxygen, argon, ozone, nitrogen trifluoride, hydrogen, and/or methane, etc. The non-gaseous component may comprise the water or aqueous solution, any chemicals dissolved therein, and any solid deposits that are carried by the water.

Typically, the separator may be a horizontal separator.

In use, the exhaust flow entering the first chamber of the separator may be directed against an inlet diverter and/or against a wall of the chamber. This may reduce the velocity of the exhaust flow. The non-gaseous component of the exhaust flow may descend into the liquid contained within the first chamber.

In use, the flow rate of the water injected through the nozzle of the water eductor may be controlled to substantially align with the flow rate of liquid out of the separator, or vice versa. The amount of liquid in the first chamber may be maintained such that the gaseous exhaust outlet is arranged above the fill-line, and the first liquid outlet is arranged below the fill-line. This may increase the likelihood that the gaseous component of the exhaust flow may exit the separator via the gaseous exhaust outlet, and may decrease the likelihood of the gaseous component of the exhaust flow exiting the separator via the first liquid outlet.

Typically, the separator may further comprise a third chamber having a liquid inlet fluidly connected to the second liquid outlet, and a further (i.e. third) liquid outlet. The third chamber may be arranged such that liquid flows through the third chamber in a direction substantially opposite to the direction of liquid flow through the second chamber. Typically, when in use, the third chamber may be located below the second chamber.

Typically, the liquid exiting the separator may be conveyed to an acid waste treatment plant. Said acid waste treatment plant may be part of the exhaust gas abatement apparatus.

Advantageously, the third chamber may further deter the gaseous component of the exhaust flow from exiting the separator via the third liquid outlet. Instead, the gaseous component of the exhaust flow may be biased towards exiting via the gaseous exhaust outlet. The skilled person will appreciate that one or more further chambers may be present following the third chamber, and usually arranged such that liquid flows through said chamber in a direction substantially opposite to the direction of liquid flow in the preceding chamber.

The separator may comprise an inlet diverter. The inlet diverter may be configured to direct the non-gaseous component of the exhaust flow towards the liquid in the first chamber.

The separator may comprise a mist extractor. The mist extractor may be configured to substantially prevent the passage of the non-gaseous component of the exhaust flow through the gaseous exhaust outlet. Preferably, the mist extractor may provide a physical barrier to the passage of solids and/or liquids through the gaseous exhaust outlet. The mist extractor may cause liquid droplets carried by the gaseous component of the exhaust flow to coalesce and be directed back into the first chamber. The mist extractor may be arranged at or toward the gaseous exhaust outlet. The mist extractor may comprise a wire mesh, and/or a plurality of vanes.

Additionally, or alternatively, the separator may comprise a liquid level sensor in the first chamber. The liquid level sensor may be operably connected to a controller. The controller may be configured to adjust the flow rate and/or the pressure of water entering the water eductor. The liquid level sensor and controller may maintain the level of the water (fill-line) at a preferred level within the first chamber, e.g. below the gaseous exhaust outlet and/or above the first liquid outlet.

Typically, the water eductor may be configured to substantially prevent back-flow of gas through the exhaust outlet of the vacuum pump. Additionally, or alternatively, the water eductor may be configured to produce a flow rate of at least 40 slm of nitrogen through the exhaust gas inlet. Preferably, the water eductor may be configured to produce a flow rate of at least 100 slm of nitrogen through the exhaust gas inlet. The water eductor may be configured to produce a flow rate at least equal to the flow rate of the nitrogen gas being introduced into the exhaust flow. Advantageously, this may substantially prevent back-flow of gas through the exhaust outlet into the vacuum pump when in use, aiding pumping performance.

Typically, the water flow rate through the nozzle of the water eductor may be at least 0.5 gallons per minute (i.e. 2.27304 litres per minute) at 5 psi (i.e. 34.4738 kPa). Preferably, the water flow rate through the nozzle of the water eductor may be at least 5 gallons per minute (i.e. 22.7304 litres per minute) at 50 psi (i.e. 344.738 kPa). Advantageously, controlling the pressure and flow rate of the water through the nozzle of the water eductor may enable control of the vacuum produced at the inlet of the water eductor.

In some embodiments, the water eductor may have a length of less than about 200 mm, preferably less than about 160 mm. The water eductor may have a height of less than about 150 mm, preferably less than about 100 mm. The water eductor may have a width of less that about 50 mm, preferably less than about 30 mm.

Additionally, or alternatively, the separator may have a length of less than about 250 mm, preferably less than about 160 mm. The separator may have a height of less than about 150 mm, preferably less than about 100 mm. The separator may have a width of less than about 150 mm, preferably less than about 100 mm.

Advantageously, the compact design of the water eductor and/or separator may enable them to fit within the exhaust gas abatement system where space is limited. Furthermore, the compact design may allow for positioning of the water eductor and the separator closer to the vacuum pump exhaust outlet, thereby reducing the likelihood of condensation of precursor chemical vapours prior to reaching the water eductor.

Typically, the water eductor may be configured to be heated to a temperature of at least 100° C. during operation. Preferably, the water eductor may be configured to be heated to a temperature of at least 200° C. during operation. For some applications, the temperature of the vacuum pump exhaust flow may be from about 100° C. to about 200° C., or greater. In such cases, the water eductor may be heated to reduce the likelihood of condensation of precursor chemical vapours upon entering the water eductor due to a drop in the temperature. The water eductor may comprise a heating element, such as a heating tape, that is configured to maintain the water eductor at the selected temperature.

Typically, the water eductor may be manufactured from a polymeric material and/or a metallic material. Preferably, the water eductor may consist of a single material. The material(s) selected may depend on the application.

By way of example, in embodiments wherein the water eductor comprises a polymeric material, the material of the water eductor may be selected from the list comprising polypropylene, chlorinated polyvinyl chloride (CPVC), or Teflon. In embodiments wherein the water eductor is manufactured from a metallic material, the material of the water eductor may be selected from the list comprising stainless steel, acid resistant Hastelloy, copper, or brass.

For applications wherein the water eductor is heated when in use, the water eductor may preferably be manufactured from a metallic material. For example, the water eductor may comprise stainless steel.

For applications wherein the exhaust gas flow from the vacuum pump comprises inorganic acids (e.g. hydrofluoric acid or hydrochloric acid), the water eductor may preferably comprise Hastelloy steel.

Advantageously, the selection of specific materials for the water eductor according to the application may improve the lifetime of the component, and/or reduce the cost.

In a further aspect, the present invention provides a method of abating exhaust gas from a semiconductor processing chamber. The method comprises the steps of:
a. evacuating exhaust from the semiconductor processing chamber by operation of a vacuum pump;
b. conveying the exhaust exiting the vacuum pump through a water eductor, such that the exhaust is mixed with water;
c. conveying the exhaust and water mixture from the water eductor through a separator, whereby the gaseous component of the exhaust is separated from the non-gaseous component; and
d. processing the gaseous component of the exhaust in an exhaust gas abatement apparatus.

For the avoidance of doubt, further features of the vacuum pump, the water eductor, the separator, and/or the exhaust gas abatement apparatus, may be as defined in the first aspect and elsewhere herein.

Typically, step (a) may comprise operation of the vacuum pump to provide a high or ultra-high vacuum within the semiconductor processing chamber. A high vacuum may be defined as pressures from about 10-7 mbar to about 10-3 mbar. An ultra-high vacuum may be defined as pressures less than about 10⁻⁷ mbar.

Typically, the exhaust gas may be diluted with nitrogen gas. Preferably, the exhaust gas may be diluted with nitrogen gas at the exhaust of the vacuum pump. The exhaust gas may be diluted with nitrogen gas having a flow rate of about 20 slm to about 150 slm. Advantageously, this may reduce the risk of condensation of precursor chemical vapours, and may lower flammability levels.

Preferably, throughout steps (b) and (c), the water eductor may be heated to a temperature greater than about 100° C., preferably greater than about 200° C. Advantageously, this may reduce the likelihood of condensation of chemical precursor gases upon entry to the water eductor, particularly in cases where the vacuum pump exhaust gases are at elevated temperatures (e.g. temperatures greater than 100° C.).

Preferably, throughout step (b), the water eductor may provide a vacuum at the exhaust outlet of the vacuum pump to draw the exhaust flow into the water eductor. Preferably, the water eductor may provide a vacuum at the exhaust outlet of the vacuum pump sufficient to induce a flow rate at least equal to the flow rate of nitrogen dilution. More preferably, the water eductor may provide vacuum sufficient to induce a flow rate of at least 40 slm of nitrogen through the exhaust gas inlet of the water eductor. Advantageously, this may substantially prevent back-flow of gases through the exhaust outlet of the vacuum pump.

In a further aspect, the present invention provides the use of a water eductor and a separator in an exhaust gas abatement system for semiconductor production, wherein the water eductor and the separator are arranged between a vacuum pump and exhaust gas abatement apparatus such that exhaust from the vacuum pump is conveyed to the separator via the water eductor.

Preferably, the water eductor and the separator may be arranged directly adjacent to the exhaust outlet of the vacuum pump. The vacuum pump, water eductor, separator, and exhaust gas abatement apparatus may be arranged in series and may be fluidly connected.

For the avoidance of doubt, further features of the vacuum pump, the water eductor, the separator, and/or the exhaust gas abatement apparatus are as defined in the preceding aspects and elsewhere herein.

Advantageously, the use of a water eductor and separator according to the present invention may provide a low cost and efficient mechanism for removing water-reactive chemical precursor gases from a semiconductor processing exhaust gas flow. Thereby, condensation of said chemical precursor gases within the exhaust line may be reduced, and the mean time between failure of the exhaust gas abatement system may be increased. This may enable safer and less regular maintenance.

For the avoidance of doubt, all aspects and embodiments described herein may be combined mutatis mutandis. It is also to be understood that this invention is not limited to the embodiments and aspects set forth in the following detailed description or illustrated in the drawings. The invention may be implemented in various other embodiments and is capable of being implemented in alternative ways not expressly disclosed herein.

Also, it is to be understood that the phraseology and terminology used herein are for the purpose of description and should not be regarded as limiting. The use of “including” and “comprising” and variations thereof is meant to encompass the items listed thereafter and equivalents thereof as well as additional items and equivalents thereof. Further, enumeration may be used in the description of various embodiments. Unless otherwise expressly stated, the use of enumeration should not be construed as limiting the invention to any specific order or number of components. Nor should the use of enumeration be construed as excluding from the scope of the invention any additional steps or components that might be combined with or into the enumerated steps or components.

The summary is provided to introduce a selection of concepts in a simplified form that are further described in the detailed description. This summary is not intended to identify key features or essential features of the claimed subject matter, nor is it intended to be used as an aid in determining the scope of the claimed subject matter.

### BRIEF DESCRIPTION OF THE FIGURES

Preferred features of the present invention will now be described, by way of example, with reference to the accompanying figures, in which:

FIG. 1 shows a schematic of a typical semiconductor processing system of the prior art;

FIG. 2 shows a cross-sectional view of a water eductor suitable for use in an exhaust gas abatement system according to the present invention;

FIG. 3 shows a cross-sectional view of a water eductor and a separator suitable for use in an exhaust gas abatement system according to the present invention;

FIG. 4 shows a cross-sectional view of a vacuum pump, a water eductor and a separator suitable for use in an exhaust gas abatement system according to the present invention;

FIG. 5 shows a flow diagram of a method according to the present invention.

### DETAILED DESCRIPTION

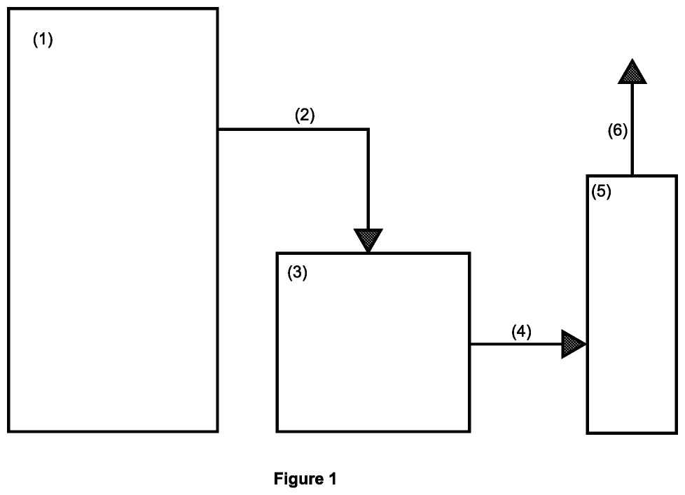

FIG. 1 illustrates a schematic of a typical semiconductor processing system of the prior art. The system comprises a semiconductor processing chamber (1). In said chamber (1), single crystal silicon wafers are processed via a plurality of lithography, deposition, and/or etch steps using various precursor chemical vapours. This processing is performed under high or ultra-high vacuum. Accordingly, the semiconductor processing chamber (1) is connected via a fore line (2) to a vacuum pump (3).

The vacuum pump (3) may be, for example, a dry vacuum pump. In use, the vacuum pump (3) is configured to evacuate the semiconductor processing chamber (1) to a high vacuum. The exhaust flow leaves the vacuum pump (3) through the vacuum pump exhaust line (4).

In use, the exhaust flow in the vacuum pump exhaust line (4) may be diluted with nitrogen gas to reduce the likelihood of condensation of the exhaust flow in the vacuum pump exhaust line (4).

The nitrogen diluted exhaust flow may be conveyed through the vacuum pump exhaust line (4) to the exhaust gas abatement apparatus (5), where the exhaust gas is processed. Said processing comprises exposing the exhaust gas to high temperatures generated either by an inward-fired combustion chamber, plasma chamber, or electric arc discharge. The processed exhaust gases are then allowed to exit the exhaust gas abatement apparatus (5) through a gas outlet (6).

It has been found that in such systems, a significant proportion of the precursor chemical vapours exit the semiconductor processing chamber (1) in the exhaust flow through the fore line (2), and pass through the vacuum pump (3), vacuum pump exhaust line (4), and into the exhaust gas abatement apparatus (5). This is undesirable as condensation of the precursor chemical vapours can form deposits and react with any water in the system. It has been found that deposit formation may be particularly prevalent in the vacuum pump exhaust line (4), requiring an increased frequency of maintenance.

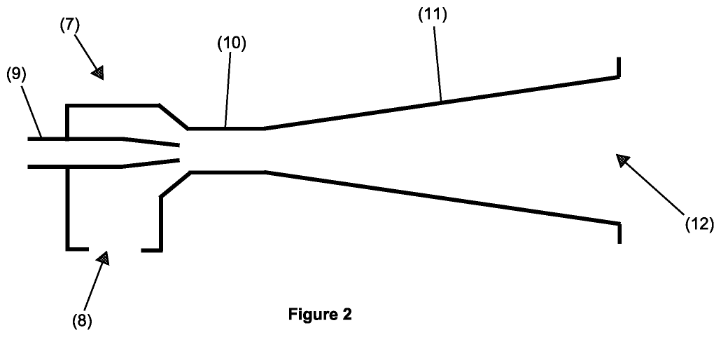

FIG. 2 illustrates a cross-sectional view of a water eductor (7) suitable for use in an exhaust gas abatement system according to the present invention. The water eductor (7) comprises an inlet (8) configured to be coupled to the exhaust outlet of the vacuum pump (not shown). Preferably, the inlet (8) may be directly connected to the exhaust outlet of the vacuum pump. Alternatively, the inlet (8) may be coupled to the exhaust outlet of the vacuum pump by an exhaust gas line.

The water eductor (7) further comprises a nozzle (9) configured for the injection of water. In use, the injected water may provide the motive fluid for the Venturi effect produced by the water eductor (7). In use, pressurised water may be supplied to the nozzle (9) from a pump (not shown). Typically, the water flow rate through the nozzle (9) of the water eductor (7) may be at least 0.5 gallons per minute (i.e. 2.27304 litres per minute) at 5 psi (i.e. 34.4738 kPa), preferably at least 5 gallons per minute (i.e. 22.7304 litres per minute) at 50 psi (i.e. 344.738 kPa).

The water eductor further comprises a mixing throat (10). In use, the water injected through the nozzle (9) mixes in the mixing throat (10) with the exhaust flow entering through the inlet (8). The cross-sectional area of the water eductor (7) may narrow at the mixing throat (10). This may advantageously improve mixing.

The water eductor (7) further comprises an expander diffuser (11) coupled to the mixing throat (10). The chamber defining the expander diffuser (11) may have an increasing cross-sectional area in the direction of an outlet (12) of the water eductor (7). The chamber may have a first cross-sectional area adjacent the mixing throat (10), and a second cross-sectional area adjacent the outlet (12) of the water eductor (7), wherein the first cross-sectional area is smaller than the second cross-sectional area. The cross-sectional area of the chamber defining the expander diffuser (11) may increase substantially continuously between the first cross-sectional area and the second cross-sectional area. The chamber defining the expander diffuser (11) may be substantially frusto-conical. In use, water and the exhaust flow may be conveyed through said chamber.

In use, the water eductor (7) may provide a vacuum at the inlet (8) via the Venturi effect. Advantageously, this may draw gas out of the exhaust outlet of the vacuum pump, and may reduce backflow of gas through said exhaust outlet.

In use, the water eductor (7) may be heated to a temperature of at least 100° C., preferably at least 200° C. Advantageously, this may reduce the likelihood of condensation of precursor chemical vapours that may be present in the exhaust gas flow. In such embodiments, the water eductor (7) is made from a metallic material, for example stainless steel.

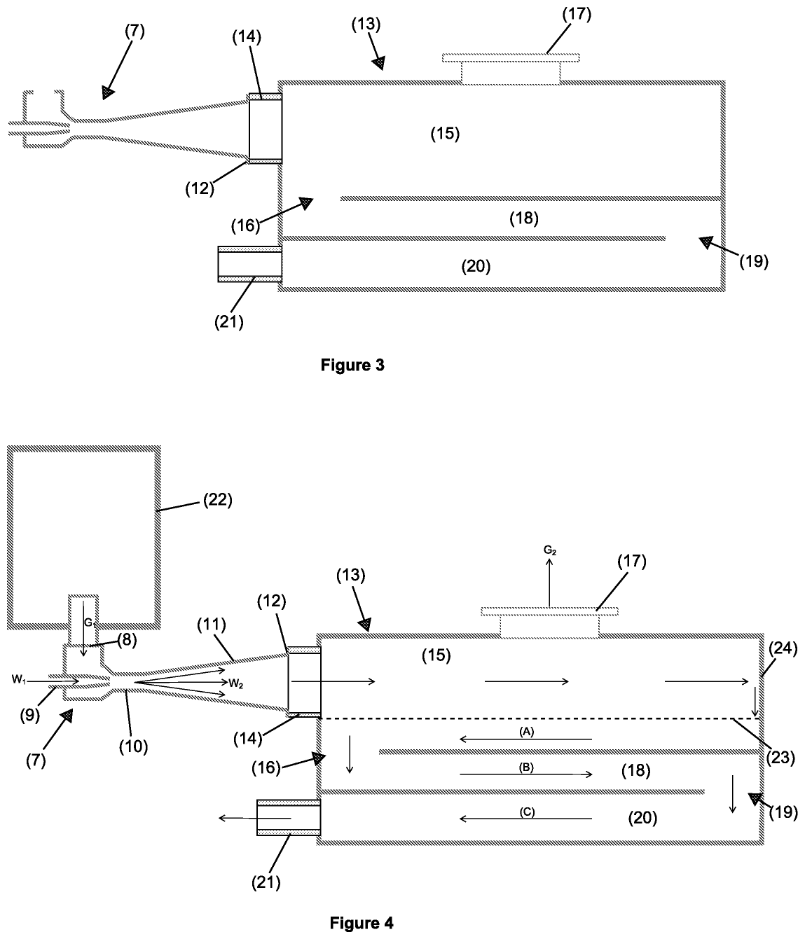

FIG. 3 illustrates a cross-sectional view of a water eductor (7) and a separator (13) suitable for use in exhaust gas abatement systems according to the present invention. The water eductor (7) is as shown in FIG. 2, accordingly corresponding reference numbers will be used and the description of its features will not be repeated.

The separator (13) comprises an inlet (14) coupled to the outlet (12) of the water eductor (7). The separator (13) further comprises a first chamber (15) comprising a first liquid outlet (16) and a gaseous exhaust outlet (17). The first chamber (15) is configured to, in use, be partially filled with liquid such that an uppermost surface of the liquid defines a fill-line. In use, the first liquid outlet (16) is arranged below the liquid level and the gaseous exhaust outlet (17) is arranged above the liquid level, as shown in FIG. 4. The gaseous exhaust outlet (17) is connected to the abatement apparatus (not shown).

The separator (13) further comprises a second chamber (18) having an inlet fluidly connected to the first liquid outlet (16) of the first chamber (15), and a second liquid outlet (19). As will be shown in FIG. 4, the second liquid outlet (19) is arranged such that, in use, liquid flows through the second chamber (18) in a direction substantially opposite to the direction of liquid flow through the first chamber (15).

The separator (13) is configured, in use, to separate the gaseous component of the exhaust flow from the non-gaseous component of the exhaust flow. The gaseous component of the exhaust flow may comprise any gases that are not dissolved in the water in the water eductor (7), and/or gaseous products of reactions between the exhaust flow and the water. The non-gaseous component may comprise the water, any chemicals dissolved therein, and any solid deposits that are carried in the water.

In this embodiment, the separator (13) further comprises a third chamber (20). The third chamber (20) has a liquid inlet fluidly connected to the second liquid outlet (19). The third chamber has a third liquid outlet (21). The third chamber (20) may be arranged such that, in use, liquid flows through the third chamber (20) in a direction substantially opposite to the direction of liquid flow through the second chamber (18). In this embodiment, the third liquid outlet (21) provides the outlet of the separator (13).

FIG. 4 shows a cross-sectional view of a vacuum pump (22), a water eductor (7) and a separator (13) suitable for use in exhaust gas abatement systems according to the present invention. The water eductor (7) and separator (13) are as described in relation to FIGS. 2 and 3, respectively, and corresponding reference numerals will be used.

In use, the semiconductor processing chamber (not shown) is evacuated by the vacuum pump (22). The exhaust flow from the semiconductor processing chamber, and therefore the vacuum pump (22), may include precursor chemical vapours. The motive flow of water (W₁) is injected through the nozzle (9) at a predetermined pressure and flow rate. The exhaust flow (G₁) exits the vacuum pump (22) and is conveyed into the water eductor (7) through the inlet (8). The water (W₁) mixes with the exhaust gas (G₁) in the mixing throat (10), and transfers kinetic energy thereto. Most of the water-reactive components of the exhaust gas flow may dissolve in the water. Preferably, this may include water-reactive precursor chemical vapours and/or inorganic acids present in the exhaust gas flow.

The exhaust flow (W₂) (i.e. mixture of exhaust gases and water) then exits the mixing throat (10) into the expander diffuser (11). As the cross-sectional area of the chamber defining the expander diffuser (11) increases in the direction of the outlet (12), the velocity of the exhaust flow (W₂) reduces and the pressure increases. Thus, due to the pressure differential generated, a vacuum is created at the inlet (8) to draw exhaust gas (G₁) into the water eductor (7).

The exhaust flow (W₂) then exits the expander diffuser (11) and enters the first chamber (15) of the separator (13) via the inlet (14). When in use, first chamber (15) is partially filled with liquid such that an uppermost surface of the liquid defines a fill-line (23). The fill-line (23) is maintained such that the first liquid outlet (16) is arranged below the fill-line (23), and the gaseous exhaust outlet (17) is arranged above the fill-line (23).

The exhaust flow (W 2) entering the first chamber (15) of the separator (13) is directed against an inlet diverter or against a wall (24) of the first chamber (15). This may reduce the velocity of the exhaust flow (W₂), and the non-gaseous component thereof may flow into the liquid contained within the first chamber (15). The direction (A) of liquid flow through the first chamber (15) is towards the liquid outlet (16).

The liquid then enters the second chamber (18). The direction (B) of liquid flow through the second chamber (18) is towards the second liquid outlet (19). Said direction (B) is substantially opposite to the direction (A) of liquid flow through the first chamber (15).

The liquid then enters the third chamber (20). The direction (C) of liquid flow through the third chamber (20) is towards the third liquid outlet (21). Said direction (C) is substantially opposite to the direction (B) of liquid flow through the second chamber (18). The first chamber (15) may be positioned above the second chamber (18). The second chamber may be positioned above the third chamber (20).

The alternating directions (A,B,C) of water flow through the first (15), second (18), and third chamber (20), respectively, may reduce the likelihood of the gaseous component of the exhaust flow from exiting the separator (13) via the third outlet (21). Instead, the gaseous component (G₂) of the exhaust flow is biased to exit the separator (13) through the gaseous exhaust outlet (17).

Although not shown in this embodiment, a mist diffuser may be present to reduce the likelihood of liquid droplets passing through the gaseous exhaust outlet (17).

A water level sensor (not shown) may be present in the first chamber (15). The water level sensor may be coupled to a controller. The controller may be configured adjust the water flow rate through the nozzle (9) to ensure that the fill-line (23) is maintained at an appropriate level within the first chamber (15).

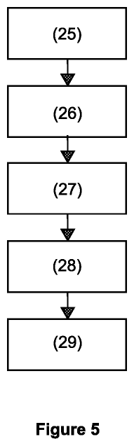

FIG. 5 shows a flow diagram of a method according to the present invention. For the avoidance of doubt, features of the vacuum pump, water eductor, separator, and exhaust gas abatement apparatus, may be as defined in any other aspect or embodiment described herein.

The method comprises the steps of evacuating exhaust from the semiconductor processing chamber by operation of a vacuum pump (25). This step may include operation of the vacuum pump to produce a high vacuum or ultra-high vacuum in the semiconductor processing chamber. Preferably, as the exhaust exits the vacuum pump, it may be diluted with nitrogen gas (26).

Then, the exhaust is conveyed from the vacuum pump through a water eductor, such that the exhaust is mixed with water (27). Preferably, the water eductor may provide a vacuum at the exhaust outlet of the vacuum pump sufficient to draw the exhaust into the water eductor. More preferably, the water eductor may provide a flow rate sufficient to pull at least 40 slm of nitrogen through the exhaust inlet. Preferably, the water eductor is heated to a temperature greater than about 100° C., preferably greater than about 200° C.

Then, the exhaust and water mixture is conveyed from the water eductor through a separator, whereby the gaseous component of the exhaust is separated from the non-gaseous component (28).

Then, the gaseous component is processed in an exhaust gas abatement apparatus (29). The non-gaseous component is discharged through a liquid outlet of the separator.

For the avoidance of doubt, features of any aspects or embodiments recited herein may be combined mutatis mutandis. It will be appreciated that various modifications may be made to the embodiments shown without departing from the spirit and scope of the invention as defined by the accompanying claims as interpreted under patent law, including the doctrine of equivalents. Any reference to claim elements in the singular, for example, using the articles “a”, “an”, “the” or “said”, is not to be construed as limiting the element to the singular.

Although elements have been shown or described as separate embodiments above, portions of each embodiment may be combined with all or part of other embodiments described above.

Although the subject matter has been described in language specific to structural features and/or methodological acts, it is to be understood that the subject matter defined in the appended claims is not necessarily limited to the specific features or acts described above. Rather, the specific features and acts described above are described as example forms of implementing the claims.

What is claimed is:

1. An exhaust gas abatement system for use in semiconductor processing, comprising:
a vacuum pump comprising an exhaust outlet;
a water eductor coupled to the exhaust outlet of the vacuum pump;
a separator coupled to the water eductor; and
an exhaust gas abatement apparatus, preferably an abatement furnace, coupled to a gaseous exhaust outlet of the separator;
wherein the system is configured such that, in use, an exhaust flow from the exhaust outlet of the vacuum pump is conveyed to the separator via the water eductor,
and wherein the separator is configured, in use, to separate a gaseous component of the exhaust flow and a non-gaseous component of the exhaust flow.

2. The exhaust gas abatement system according to claim 1, wherein the water eductor comprises:
an inlet coupled to the exhaust outlet of the vacuum pump;
a nozzle configured for the injection of water;
a mixing throat, in which, when in use, said injected water mixes with the exhaust flow from the vacuum pump; and
an expander diffuser coupled to the mixing throat and defined by a chamber having an increasing cross-sectional area in the direction of an outlet of the water eductor.

3. The exhaust gas abatement system according to claim 1, wherein the separator comprises:
an inlet coupled to the outlet of the water eductor;
a first chamber comprising a first liquid outlet and the gaseous exhaust outlet, and configured to be partially filled with liquid such that an uppermost surface of the liquid defines a fill-line, and wherein the first liquid outlet is arranged below the fill-line and the gaseous exhaust outlet is arranged above the fill-line; and, preferably,
a second chamber comprising a liquid inlet in fluid communication with the first liquid outlet of the first chamber, and the second chamber having a further liquid outlet, wherein the second chamber is arranged such that, in use, liquid flows through the second chamber in a direction substantially opposite to the direction of liquid flow through the first chamber.

4. The exhaust gas abatement system according to claim 3, wherein the separator further comprises a third chamber, the third chamber having a liquid inlet fluidly connected to the second liquid outlet and a further liquid outlet, said third chamber being arranged such that liquid flows through the third chamber in a direction substantially opposite to the direction of liquid flow through the second chamber.

5. The exhaust gas abatement system according to claim 3, wherein the separator further comprises an inlet diverter, and/or a mist extractor, and/or a liquid level sensor in the first chamber.

6. The exhaust gas abatement system according to claim 1, wherein the water eductor is configured to substantially prevent back-flow of gas through the exhaust outlet of the vacuum pump, and/or wherein the water eductor is configured to produce a flow rate of at least 40 slm of nitrogen through the inlet.

7. The exhaust gas abatement system according to claim 1, wherein the water flow rate through the nozzle of the water eductor is at least 0.5 gallons per minute at 5 psi, preferably at least 5 gallons per minute at 50 psi.

8. The exhaust gas abatement system according to claim 1, wherein the water eductor has a length of less than about 200 mm, preferably less than about 160 mm; a height of less than about 150 mm, preferably less than about 100 mm; and a width of less that about 50 mm, preferably less than about 30 mm.

9. The exhaust gas abatement system according to claim 1, wherein the separator has a length of less than about 250 mm, preferably less than about 160 mm; a height of less than about 150 mm, preferably less than about 100 mm; and a width of less than about 150 mm, preferably less than about 100 mm.

10. The exhaust gas abatement system according to claim 1, wherein the water eductor is configured to be heated to a temperature of at least 100° C. during operation, preferably at least 200° C.

11. The exhaust gas abatement system according to claim 1, wherein the water eductor is manufactured from a polymeric material and/or a metallic material.

12. A method of abating exhaust gas from a semiconductor processing chamber, comprising the steps of:
a. evacuating exhaust from the semiconductor processing chamber by operation of a vacuum pump;
b. conveying the exhaust exiting the vacuum pump through a water eductor, such that the exhaust is mixed with water;
c. conveying the exhaust and water mixture from the water eductor through a separator, whereby a gaseous component of the exhaust is separated from a non-gaseous component; and
d. processing the separated gaseous component of the exhaust in an exhaust gas abatement apparatus.

13. The method according to claim 12, wherein throughout steps (b) and (c), the water eductor is heated to a temperature greater than about 100° C., preferably greater than about 200° C.

14. The method according to claim 12, wherein throughout step (b) the water eductor provides a vacuum at the exhaust outlet of the vacuum pump to draw the exhaust into the water eductor.

15. The use of a water eductor and a separator in an exhaust gas abatement system for semiconductor production, wherein the water eductor and the separator are arranged between a vacuum pump and exhaust gas abatement apparatus such that exhaust from the vacuum pump is conveyed to the separator via the water eductor.
